(19) United States
(12) Patent Application Publication
(10) Pub. No.: US 2025/0338444 A1
(43) Pub. Date: Oct. 30, 2025

(54) IMMERSION COOLING SYSTEM

(71) Applicant: AEWIN TECHNOLOGIES CO., LTD., New Taipei City (TW)

(72) Inventor: Cheng-En LIU, New Taipei City (TW)

(21) Appl. No.: 19/016,946

(22) Filed: Jan. 10, 2025

(30) Foreign Application Priority Data
Apr. 30, 2024 (TW) 113116197

(51) Int. Cl. H05K 7/20

(52) U.S. Cl. CPC H05K 7/20327; H05K 7/203; H05K 7/20318; H05K 7/20818

(57) ABSTRACT

An immersion cooling system is provided and includes a box body, a condensing unit and a plurality of tank bodies. The box body has a first accommodating space, a second accommodating space and a water collecting tank connected to the second accommodating space. The condensing unit is arranged in the second accommodating space. The plurality of tank bodies are arranged in the first accommodating space, and each of the plurality of tank bodies has a first valve unit and a second valve unit.

### CROSS-REFERENCE TO RELATED APPLICATIONS

This application claims priority to Taiwan Application Serial No. 113116197, filed on Apr. 30, 2024. The entirety of the above-mentioned patent application is hereby incorporated by reference herein and made a part of this specification.

### BACKGROUND

### 1. Technical Field

The present disclosure relates to a cooling system, and more particularly, to an immersion cooling system having an independent separation mechanism of multiple tanks and condensers.

### 2. Description of Related Art

The two-phase immersion cooling method utilizes the phase conversion between the gas state and the liquid state of the water-cooling liquid to take away heat. Specifically, the water-cooling liquid in the sealed tank absorbs the heat energy generated by the heating element and gasifies, then the gasified water-cooling liquid condenses on a condenser after contacting the condenser, and droplets of the water-cooling liquid condensed on the condenser fall back into the water-cooling liquid by gravity, thereby achieving the heat dissipation effect of the heating element via this circulation.

However, the existing two-phase immersion cooling method still has the problem of common vapor layers, resulting in uneven vapor distribution and poor condensation effect. In addition, when the equipment is shut down and the cover is opened, the remaining water-cooling liquid vapor will escape, causing the water- cooling liquid to be replenished and increasing costs.

### SUMMARY

The present disclosure provides an immersion cooling system, which comprises: a box body having a first accommodating space, a second accommodating space and a water collecting tank connected to the second accommodating space; a condensing unit arranged in the second accommodating space; and a plurality of tank bodies arranged in the first accommodating space, and each of the plurality of tank bodies having a first valve unit and a second valve unit, wherein each of the plurality of tank bodies contains a heat dissipation medium respectively, the heat dissipation medium gasifies after absorbing heat energy, the gasified heat dissipation medium is introduced into the second accommodating space via the first valve unit, so that the gasified heat dissipation medium is condensed and liquefied via heat exchange by the condensing unit, and the liquefied heat dissipation medium is introduced into the water collecting tank to be guided back to the tank body via the second valve unit.

In the aforementioned immersion cooling system, each of the plurality of tank bodies is provided with a heating unit.

In the aforementioned immersion cooling system, each of the plurality of tank bodies defines a vapor space and a liquid storage space connected to the vapor space, the heating unit corresponds to the liquid storage space located in the tank body, and the liquefied heat dissipation medium is accommodated in the liquid storage space, so that the heating unit is immersed in the liquefied heat dissipation medium.

In the aforementioned immersion cooling system, the vapor space and the liquid storage space are arranged up and down along a direction of gravity, the vapor space is connected to the first valve unit, the liquid storage space is connected to the second valve unit, and the vapor space and the liquid storage space are not connected to the first accommodating space.

In the aforementioned immersion cooling system, each of the plurality of tank bodies has a cover plate, and the cover plate is adjacent to the first valve unit and used to separate the vapor space and the first accommodating space.

In the aforementioned immersion cooling system, the first valve unit and the second valve unit are arranged up and down along a direction of gravity, and the first valve unit and the second valve unit respectively correspond to an upper side and a lower side of the water collecting tank.

In the aforementioned immersion cooling system, the second accommodating space and the water collecting tank are arranged up and down along a direction of gravity.

In the aforementioned immersion cooling system, the first valve unit is a one-way valve, and the second valve unit is a three-way valve or a one-way valve.

In the aforementioned immersion cooling system, the immersion cooling system further comprises a backup side tank, wherein the second valve unit is connected to the backup side tank and the tank body, so that the heat dissipation medium located in the tank body is able to be directed to the backup side tank via the second valve unit.

In the aforementioned immersion cooling system, the plurality of tank bodies are arranged side by side in the first accommodating space in a direction perpendicular to a direction of gravity.

To sum up, in the immersion cooling system of the present disclosure, the plurality of tank bodies are separated from each other, so that the heat dissipation cycles in the plurality of tank bodies are independent, such that the failed heating unit is shut down and replaced without shutting down all heating units. In addition, the gasified heat dissipation medium is concentrated in the second accommodating space, and there will be no problem of uneven distribution of vapor. Therefore, the condensation efficiency of the condensing unit can be increased, and the air pressure in each tank body is small, so there is no risk of the tank body being broken by excessive pressure. Furthermore, to replace a failed heating unit, only the corresponding cover plate needs to be opened, and there is no need to open the corresponding cover plates of all heating units. Therefore, the gasified heat dissipation medium is less likely to escape into the atmosphere, thus saving the cost of replenishing the heat dissipation medium.

### BRIEF DESCRIPTION OF THE DRAWINGS

FIG. 1 is a three-dimensional schematic view of an immersion cooling system of the present disclosure.

FIG. 2 is a schematic cross-sectional view of the immersion cooling system of the present disclosure.

FIG. 3 is a schematic cross-sectional view of the immersion cooling system according to another embodiment of the present disclosure.

### DETAILED DESCRIPTION

The following describes the implementation of the present disclosure with examples. Those skilled in the art can easily understand other advantages and effects of the present disclosure from the contents disclosed in this specification, and can implement or apply the present disclosure via other different embodiments.

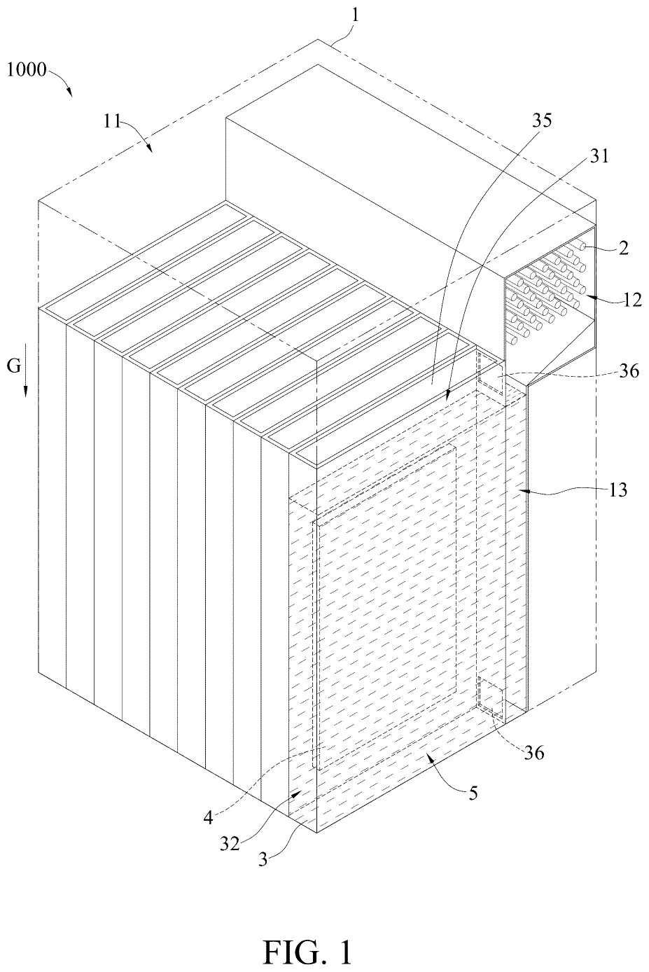

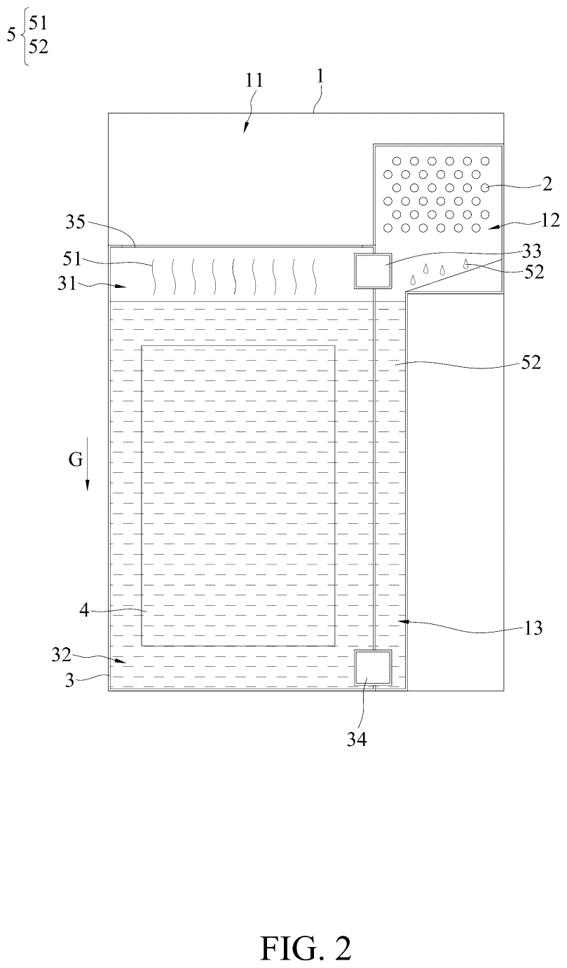

Referring to FIG. 1 and FIG. 2, an immersion cooling system 1000 of the present disclosure includes a box body 1, a condensing unit 2 and a plurality of tank bodies 3. The structure of each element and the connection relationship between each other will be described in detail below, wherein some figures show the direction of gravity G.

The box body 1 can specifically be a two-phase immersed cooling positive high-pressure sealed tank, and the two-phase immersed cooling positive high-pressure sealed tank has a first accommodating space 11, a second accommodating space 12 and a water collecting tank 13 defined therein. The first accommodating space 11 and the second accommodating space 12 or the water collecting tank 13 can be separated from each other by partitions or the plurality of tank bodies 3, while the second accommodating space 12 is connected to the water collecting tank 13. In one embodiment, the second accommodating space 12 and the water collecting tank 13 are arranged up and down along the direction of gravity G, and the first accommodating space 11 is located on one side of the second accommodating space 12 and the water collecting tank 13.

The condensing unit 2 is arranged in the second accommodating space 12. In one embodiment, the condensing unit 2 may be a condenser, such as a U-shaped condenser, a straight condenser, or a serpentine condenser, wherein both ends of the condenser can be connected to a loop-shaped pipe, and a heat exchange device (such as a heat pipe), a water-cooling radiator (such as a fan), and a pump can be disposed on the loop-shaped pipe, and wherein the pump can drive the water-cooling liquid in the condenser and the loop-shaped pipe.

The plurality of tank bodies 3 are each roughly in the shape of a rectangular parallelepiped, and are arranged side by side in the first accommodating space 11 along a direction perpendicular to the direction of gravity G, thereby separating the first accommodating space 11 and the water collecting tank 13. In other embodiments, the first accommodating space 11 and the water collecting tank 13 can also be separated by a partition first. At this time, the partition needs to have openings for a first valve unit 33 and a second valve unit 34 to pass through, but the present disclosure is not limited to as such.

Each tank body 3 is independent and has a vapor space 31 and a liquid storage space 32 connected to the vapor space 31 defined therein. Two openings 36 can be opened on one side plate separating the first accommodating space 11 and the water collecting tank 13. The two openings 36 are used to install the first valve unit 33 and the second valve unit 34 respectively (the first valve unit 33 and the second valve unit 34 are omitted in FIG. 1 for a clearer illustration). One opening 36 is close to the top side of each tank body 3, and the other opening 36 is close to the bottom side of each tank body 3, so that the first valve unit 33 and the second valve unit 34 are arranged up and down along the direction of gravity G, and the first valve unit 33 and the second valve unit 34 respectively correspond to the upper and lower sides of the water collecting tank 13.

The vapor space 31 and the liquid storage space 32 are arranged up and down along the direction of gravity G. The vapor space 31 is connected to the first valve unit 33 to accommodate a gasified heat dissipation medium 51. The liquid storage space 32 is connected to the second valve unit 34 and is used to accommodate a liquefied heat dissipation medium 52. The liquid storage space 32 in each tank body 3 can be provided with a heating unit 4, and the heating unit 4 can be immersed in the liquefied heat dissipation medium 52. In one embodiment, the boundary between the vapor space 31 and the liquid storage space 32 can be determined by the liquefied heat dissipation medium 52. As long as the heating unit 4 can be completely immersed in the liquefied heat dissipation medium 52, the horizontal plane of the liquefied heat dissipation medium 52 is the boundary, and the boundary is generally adjacent to but not in contact with the first valve unit 33.

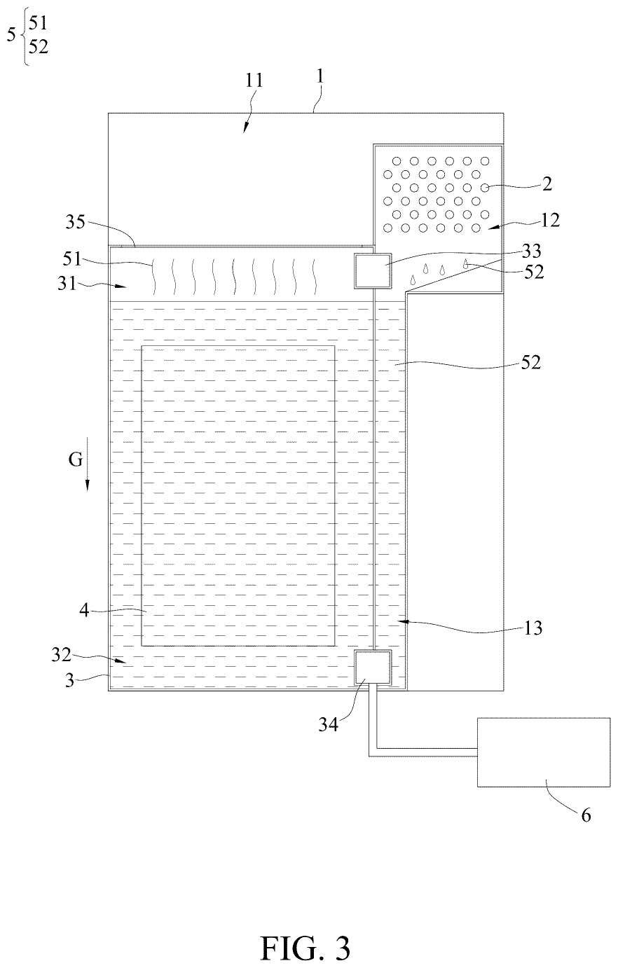

In one embodiment, the first valve unit 33 is a one-way valve, which allows the vapor space 31 and the second accommodating space 12 to be connected to each other. The second valve unit 34 is a three-way valve, which allows the liquid storage space 32 and the water collecting tank 13 to be connected to each other, and can also be connected to a backup side tank 6, as shown in FIG. 3. By controlling the second valve unit 34, the liquid storage space 32 and the water collecting tank 13 can be connected to each other, but not connected to the backup side tank 6, or the liquid storage space 32 and the backup side tank 6 can be connected to each other, but not connected to the water collecting tank 13, so as to guide a heat dissipation medium 5 to a desired space.

In other embodiments, the second valve unit 34 can also be a one-way valve connected to the liquid storage space 32 and the water collecting tank 13, and the second valve unit 34 can be changed to be connected to the liquid storage space 32 and the backup side tank 6 when needed, wherein a pump is used to guide the heat dissipation medium 5 from the liquid storage space 32 to the backup side tank 6.

In one embodiment, the heat dissipation medium 5 can be, for example, non-conductive water-cooling liquid, and the heating unit 4 can be, for example, a 2U server (a server that occupies two units of a standard server rack), wherein there are, for example, central processing units, graphics chips, other types of chips, or other heat sources inside the 2U server that generate heat, but the present disclosure is not limited to as such.

The top side of each tank body 3 may have a cover plate 35 adjacent to the first valve unit 33, wherein the cover plate 35 can be used to separate the vapor space 31 and the first accommodating space 11, and can be locked and sealed on the top side of each tank body 3, or can be detached from the top side of each tank body 3. When the cover plate 35 is closed on the top side of one of the tank bodies 3, the vapor space 31 and the liquid storage space 32 are not connected to the first accommodating space 11, and are not connected to the vapor spaces 31 and the liquid storage spaces 32 of other tank bodies 3.

The immersion cooling system 1000 of the present disclosure operates as follows. The liquefied heat dissipation medium 52 in the liquid storage space 32 gasifies after absorbing the heat energy generated by the heating unit 4, wherein the gasified heat dissipation medium 51 moves to the vapor space 31 and moves to the second accommodating space 12 via the first valve unit 33, and wherein, at this time, the condensing unit 2 allows the gasified heat dissipation medium 51 to perform heat exchange. After heat exchange between the water-cooling liquid in the condensing unit 2 and the gasified heat dissipation medium 51, the heated water-cooling liquid will flow along the loop-shaped pipe to the heat exchange device for cooling, and the pump can drive the cooled water-cooling liquid to return to the condensing unit 2 via the loop-shaped pipe for heat exchange in the next cycle. The gasified heat dissipation medium 51 is condensed and liquefied after heat exchange, and the liquefied heat dissipation medium 52 drips from the condensing unit 2 and is concentrated in the water collecting tank 13. Afterwards, the liquefied heat dissipation medium 52 can be guided back to the liquid storage space 32 in the tank body 3 via the second valve unit 34 for the next heat dissipation cycle.

Since the plurality of vapor spaces 31 and liquid storage spaces 32 in the plurality of tank bodies 3 of the present disclosure are separated from each other, and the corresponding first valve unit 33 and the second valve unit 34 are used to control the entry and exit of the heat dissipation medium 5, so the heat dissipation cycle of the heat dissipation medium 5 in each tank body 3 is independent. When the heating unit 4 in a certain tank body 3 fails, only the failed heating unit 4 needs to be stopped and drain the heat dissipation medium 5 in the corresponding tank body 3 to replace the failed heating unit 4, so there is no need to stop all heating units 4 and drain all heat dissipation media 5.

An example of an operation process of exchanging the heating unit 4 of the immersion cooling system 1000 of the present disclosure is as follows. First, the heating unit 4 in the tank body 3 to be replaced is stopped, the first valve unit 33 is closed, and the second valve unit 34 is opened to guide the liquefied heat dissipation medium 52 to the backup side tank 6. After draining the liquefied heat dissipation medium 52, the second valve unit 34 is closed, and then the first valve unit 33 is opened to discharge the gasified heat dissipation medium 51 into the second accommodating space 12, and the first valve unit 33 is closed. Finally, the cover plate 35 is opened and the heating unit 4 is replaced. In one embodiment, the tank body 3 may have other valves connected to the external space, wherein the valves can be opened during the above operation process to ensure pressure balance in the tank body 3, but the present disclosure is not limited to as such.

To sum up, in the immersion cooling system of the present disclosure, the plurality of tank bodies are separated from each other, so that the heat dissipation cycles in the plurality of tank bodies are independent, such that the failed heating unit is shut down and replaced without shutting down all heating units. In addition, the gasified heat dissipation medium is concentrated in the second accommodating space, and there will be no problem of uneven distribution of vapor. Therefore, the condensation efficiency of the condensing unit can be increased, and the air pressure in each tank body is small, so there is no risk of the tank body being broken by excessive pressure. Furthermore, to replace a failed heating unit, only the corresponding cover plate needs to be opened, and there is no need to open the corresponding cover plates of all heating units. Therefore, the gasified heat dissipation medium is less likely to escape into the atmosphere, thus saving the cost of replenishing the heat dissipation medium.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An immersion cooling system, comprising:
a box body having a first accommodating space, a second accommodating space and a water collecting tank connected to the second accommodating space;
a condensing unit arranged in the second accommodating space; and
a plurality of tank bodies arranged in the first accommodating space, and each of the plurality of tank bodies having a first valve unit and a second valve unit, wherein each of the plurality of tank bodies contains a heat dissipation medium respectively, the heat dissipation medium gasifies after absorbing heat energy, the gasified heat dissipation medium is introduced into the second accommodating space via the first valve unit, so that the gasified heat dissipation medium is condensed and liquefied via heat exchange by the condensing unit, and the liquefied heat dissipation medium is introduced into the water collecting tank to be guided back to the tank body via the second valve unit.

2. The immersion cooling system of claim 1, wherein each of the plurality of tank bodies is provided with a heating unit.

3. The immersion cooling system of claim 2, wherein each of the plurality of tank bodies is defined with a vapor space and a liquid storage space connected to the vapor space, the heating unit corresponds to the liquid storage space located in the tank body, and the liquefied heat dissipation medium is accommodated in the liquid storage space, so that the heating unit is immersed in the liquefied heat dissipation medium.

4. The immersion cooling system of claim 3, wherein the vapor space and the liquid storage space are arranged up and down along a direction of gravity, the vapor space is connected to the first valve unit, the liquid storage space is connected to the second valve unit, and the vapor space and the liquid storage space are free from being connected to the first accommodating space.

5. The immersion cooling system of claim 3, wherein each of the plurality of tank bodies has a cover plate, and the cover plate is positioned adjacent to the first valve unit and used to separate the vapor space and the first accommodating space.

6. The immersion cooling system of claim 1, wherein the first valve unit and the second valve unit are arranged up and down along a direction of gravity, and the first valve unit and the second valve unit respectively correspond to an upper side and a lower side of the water collecting tank.

7. The immersion cooling system of claim 1, wherein the second accommodating space and the water collecting tank are arranged up and down along a direction of gravity.

8. The immersion cooling system of claim 1, wherein the first valve unit is a one-way valve, and the second valve unit is a three-way valve or a one-way valve.

9. The immersion cooling system of claim 1, further comprising a backup side tank, wherein the second valve unit is connected to the backup side tank and the tank body, so that the heat dissipation medium located in the tank body is able to be directed to the backup side tank via the second valve unit.

10. The immersion cooling system of claim 1, wherein the plurality of tank bodies are arranged side by side in the first accommodating space in a direction perpendicular to a direction of gravity.
